(19) United States
(12) Patent Application Publication
(10) Pub. No.: US 2025/0290970 A1
(43) Pub. Date: Sep. 18, 2025

(54) LIGHTING TEST METHOD, LIGHTING TEST SYSTEM, AND ELECTRONIC DEVICE

(71) Applicant: Samsung Display Co., LTD., Yongin-si (KR)

(72) Inventor: Jeong Su KIM, Yongin-si (KR)

(73) Assignee: Samsung Display Co., LTD., Yongin-si (KR)

(21) Appl. No.: 18/972,302

(22) Filed: Dec. 6, 2024

(30) Foreign Application Priority Data
Mar. 18, 2024 (KR) 10-2024-0037042

(51) Int. Cl. G01R 31/26; G01R 1/073

(52) U.S. Cl. CPC G01R 31/2635; G01R 1/07314

(57) ABSTRACT

An embodiment provides a lighting test method of light emitting elements that include a second semiconductor layer, an active layer, a first semiconductor layer, and an electrode portion sequentially stacked each other on a growth substrate and spaced apart from each other. The lighting test method includes forming an electric field between a probe card electrically contacting the electrode portion on the light emitting elements, and a conductive plate facing the second semiconductor layer below the growth substrate; and testing whether the light emitting elements are lighted.

### CROSS-REFERENCE TO RELATED APPLICATION(S)

This application claims priority to and benefits of Korean Patent Application No. 10-2024-0037042 under 35 U.S.C. § 119 filed on Mar. 18, 2024 in the Korean Intellectual Property Office, the entire contents of which are incorporated herein by reference.

### BACKGROUND

### 1. Technical Field

The disclosure relates to a lighting test method, a lighting test system of a light emitting device applied to a display device, and an electronic device including the display device.

### 2. Description of the Related Art

A display device may include a light emitting element. The light emitting element may emit light, and the display device displays an image by combining the light emitted from the light emitting element.

As the light emitting element, a micro LED may be used. After the micro LED is formed on a growth substrate, it may be separated from the growth substrate, transported, and finally bonded to an electrode of the display device.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

A plurality of light emitting elements may be simultaneously formed on a growth substrate. In this case, defects may occur in some of the plurality of light emitting elements.

The disclosure provides a lighting test method and a lighting test system that may test whether a plurality of light emitting elements formed on a growth substrate are defective before transport and bonding are performed.

Embodiments provide a lighting test method of a plurality of light emitting elements that may include a second semiconductor layer, an active layer, a first semiconductor layer, and an electrode portion sequentially stacked each other on a growth substrate and spaced apart from each other, including forming an electric field between a probe card electrically contacting the electrode portion on the plurality of light emitting elements, and a conductive plate facing the second semiconductor layer below the growth substrate; and testing whether the plurality of light emitting elements are lighted.

The probe card may include a probe substrate disposed on the plurality of light emitting elements; and a plurality of probe pins protruding in a direction from the probe substrate toward the plurality of light emitting elements.

The electrode portion of each of the plurality of light emitting elements may electrically contact a corresponding probe pin among the plurality of probe pins.

The growth substrate may be disposed between the conductive plate and the second semiconductor layer in the forming of the electric field.

The conductive plate may directly contact a lower surface of the growth substrate in the forming of the electric field.

The testing of whether the plurality of light emitting elements are lighted may include obtaining an image by imaging the plurality of light emitting elements with an optical test unit; and checking whether light is emitted in areas corresponding to the plurality of light emitting elements, in the image.

The optical test unit may image the plurality of light emitting elements on the probe card.

The optical test unit may image the plurality of light emitting elements below the conductive plate, and the conductive plate may include a light-transmissive material.

The lighting test method may further include removing a defective light emitting element among the plurality of light emitting elements from the growth substrate after the testing of whether the plurality of light emitting elements are lighted.

Embodiments provide a lighting test system that may include a growth substrate; a plurality of light emitting elements that include a second semiconductor layer, an active layer, a first semiconductor layer, and an electrode portion sequentially stacked each other on the growth substrate and spaced apart from each other; a probe card disposed on the plurality of light emitting elements and moving in a direction toward the plurality of light emitting elements to electrically contact the electrode portion; a conductive plate disposed below the growth substrate and moving in a direction toward the growth substrate; and an optical test unit disposed on the probe card.

The probe card may include a probe substrate disposed on the plurality of light emitting elements; and a plurality of probe pins protruding in a direction from the probe substrate toward the plurality of light emitting elements.

The lighting test system may further include a power source electrically connected to each of the probe card and the conductive plate.

The second semiconductor layer may directly contact an upper surface of the growth substrate.

The second semiconductor layer may include a first doped portion disposed below the active layer and having a first average doping concentration; a second doped portion disposed below the first doped portion and having a second average doping concentration lower than the first average doping concentration; and a third doped portion disposed below the second doped portion and having a third average doping concentration lower than the second average doping concentration.

The electrode portion may further include an auxiliary electrode electrically contacting the first semiconductor layer on the first semiconductor layer; and a bonding electrode electrically connected to the auxiliary electrode on the auxiliary electrode.

The auxiliary electrode may include a light-transmissive material.

A planar area of the bonding electrode may be smaller than a planar area of the first semiconductor layer.

The electrode portion may further include a reflective electrode disposed between the auxiliary electrode and the bonding electrode.

A planar area of the reflective electrode may be smaller than a planar area of the first semiconductor layer.

Embodiments provide a lighting test system that may include a growth substrate; a plurality of light emitting elements that include a second semiconductor layer, an active layer, a first semiconductor layer, and an electrode portion sequentially stacked each other on the growth substrate and spaced apart from each other; a probe card disposed on the plurality of light emitting elements and moving in a direction toward the plurality of light emitting elements to electrically contact the electrode portion; a conductive plate disposed below the growth substrate and moving in a direction toward the above growth substrate; and an optical test unit disposed on the conductive plate, wherein the conductive plate may include a light-transmissive material.

Embodiments provide an electronic device that may include a processor to provide input image data; and a display device to display an image based on the input image data, wherein the display device may include a plurality of light emitting elements, and the plurality of light emitting elements may be manufactured by performing the lighting method according to embodiments of the disclosure.

The lighting test method according to embodiments provides a lighting test method for a plurality of light emitting elements directly formed on a growth substrate. Accordingly, lighting defects in the plurality of light emitting elements may be sensed before the plurality of light emitting elements are separated from the growth substrate and transported and bonded.

### BRIEF DESCRIPTION OF THE DRAWINGS

The above and other aspects and features of the disclosure will become more apparent by describing in detail embodiments thereof with reference to the attached drawings, in which:

FIG. 1 illustrates a block diagram of a display device according to embodiments of the disclosure.

FIG. 2 illustrates a block diagram of one of sub-pixels included in the display device of FIG. 1.

FIG. 3 illustrates a schematic top plan view of a display panel configuring the display device of FIG. 1.

FIG. 4 illustrates a schematic cross-sectional view of the display panel of FIG. 3 according to an embodiment.

FIG. 5 illustrates a schematic cross-sectional view of the display panel of FIG. 3 according to an embodiment.

FIG. 6 illustrates a schematic top plan view of a light emitting element array including a plurality of light emitting elements formed on a growth substrate.

FIG. 7 illustrates a schematic cross-sectional view taken along line I1-I1′ of FIG. 6.

FIG. 8 illustrates a schematic cross-sectional view of a lighting test system for performing a lighting test of the light emitting element array of FIG. 6 according to an embodiment.

FIG. 9 illustrates a schematic top plan view of an image imaged by an optical test unit included in the lighting test system of FIG. 8.

FIG. 10 illustrates a schematic cross-sectional view of an embodiment of removing a light emitting element determined to be defective in lighting based on the image of FIG. 9.

FIG. 11 illustrates a schematic cross-sectional view of a lighting test system for performing a lighting test of the light emitting element array of FIG. 6 according to an embodiment.

FIG. 12 illustrates a schematic top plan view of an image imaged by an optical test unit included in the lighting test system of FIG. 11.

FIG. 13 illustrates a schematic top plan view of one of pixels of FIG. 3 according to an embodiment.

FIG. 14 illustrates a schematic cross-sectional view taken along line X1-X1′ of FIG. 13.

FIG. 15 illustrates a block diagram of a display system according to an embodiment.

FIG. 16 to FIG. 19 illustrate schematic perspective views of application examples of the display system of FIG. 15.

### DETAILED DESCRIPTION OF THE EMBODIMENTS

Hereinafter, example embodiments will be described in detail with reference to the accompanying drawings. The following description is intended to provide a sufficient disclosure to enable the understanding of the operation of the disclosure, and any other disclosure may be omitted to avoid obscuring the scope of the disclosure. The disclosure may be embodied in different forms and is not limited to the embodiments set forth herein. The embodiments described herein are provided for the purpose of describing the technical concept in sufficient detail for those skilled in the art to readily practice it.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Throughout the specification, when it is described that an element is “connected” to another element, this includes not only being “directly connected”, but also being “indirectly connected” with another device therebetween. The terms used herein are for the purpose of describing embodiments and are not intended to limit the scope of the disclosure.

Throughout the specification, the terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Although the terms first, second, etc. may be used herein to describe various constituent elements, these constituent elements should not be limited by these terms. These terms are used to distinguish one constituent element from another. Thus, a first constituent element discussed below could be termed a second constituent element without departing from the teachings of the disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

Various embodiments are described herein with reference to sectional illustrations that are schematic illustrations. As such, variations from the shapes of the illustrations as a result, for example, of manufacturing techniques and/or tolerances, are to be expected. Thus, embodiments disclosed herein should not be construed as limited to the illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

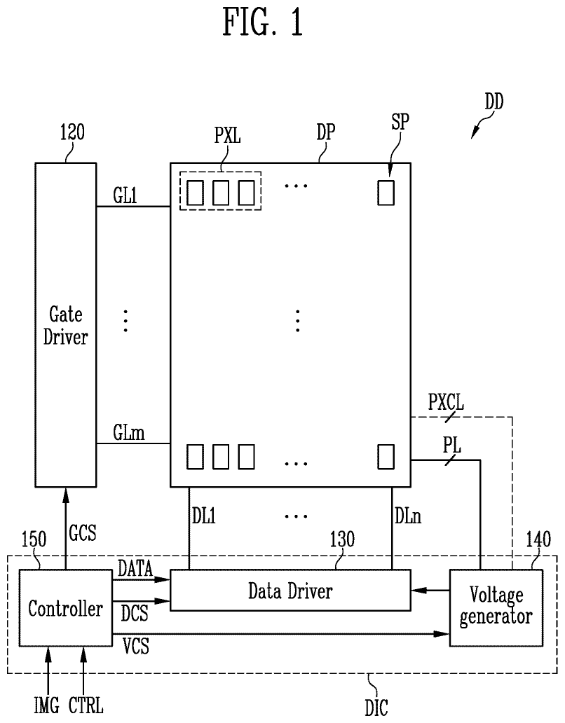

FIG. 1 illustrates a block diagram of a display device according to embodiments of the disclosure.

Referring to FIG. 1, a display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, the sub-pixels SP may respectively generate light of a color, such as red, green, blue, cyan, magenta, yellow, or the like within the spirit and the scope of the disclosure.

Two or more of the sub-pixels SP may configure one pixel PXL. For example, the pixel PXL may include three sub-pixels as shown in FIG. 1. The pixel PXL may emit light of various colors and various luminance depending on a combination of light emitted from the sub-pixels included in the pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal, and the like within the spirit and the scope of the disclosure.

The gate driver 120 may be disposed on one side or a side of the display panel DP. However, embodiments are not limited thereto. For example, the gate driver 120 may be divided into two or more drivers that are physically and/or logically divided, and these drivers may be disposed on one side or a side of the display panel DP and the other side opposite to the one side or the side. As described above, the gate driver 120 may be disposed around the display panel DP in various forms according to the embodiments.

The data driver 130 is connected to the sub-pixels SP arranged in a column direction through the first to n-th data lines DL1 to DLn. The data driver 130 receives image data (DATA) and data control signal DCS from the controller 150. The data driver 130 operates in response to the data control signal DCS. In embodiments, the data control signal DCS may include a source start signal, a source shift clock, a source output enable signal, and the like within the spirit and the scope of the disclosure.

The data driver 130 may receive voltages from the voltage generator 140. The data driver 130 may use the received voltages to apply data signals having grayscale voltages corresponding to the image data (DATA) to the first to n-th data lines DL1 to DLn. In case that a gate signal is applied to each of the first to m-th gate lines GL1 to GLn, data signals corresponding to the image data DATA may be applied to the data lines DL1 to DLm. Accordingly, the sub-pixels SP may generate light corresponding to the data signals, and the display panel DP may display an image.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device DD, such as the gate driver 120, the data driver 130, and the controller 150. The voltage generator 140 may generate a plurality of voltages by receiving an input voltage from the outside of the display device DD and regulating the received voltage.

The voltage generator 140 may generate a first power voltage and a second power voltage. The generated first and second power voltages may be provided to the sub-pixels SP through the power lines PL. In other embodiments, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, during a sensing operation to sense electrical characteristics of transistors and/or light emitting elements of the sub-pixels SP, a selectable reference voltage may be applied to the first to n-th data lines DL1 to DLn, and the voltage generator 140 may generate the reference voltage to transmit it to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide pixel control signals to the sub-pixels SP through a pixel control lines PXCL. FIG. 1 illustrates that the pixel control lines PXCL are connected between the voltage generator 140 and the display panel DP, but the embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 controls various operations of the display device DD. The controller 150 receives input image data IMG and a control signal CTRL corresponding thereto, from the outside. The controller 150 may provide the gate control signal GCS, the data control signal DCS, and the voltage control signal VCS in response to the control signal CTRL.

The controller 150 may convert the input image data IMG to be suitable for the display device DD or the display panel DP to output the image data DATA. In embodiments, the controller 150 may output the image data DATA by aligning the input image data IMG to be suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within (or in) one driver integrated circuit DIC. In other embodiments, at least one of the data driver 130, the voltage generator 140, and the controller 150 may be provided as a component separated from the driver integrated circuit DIC.

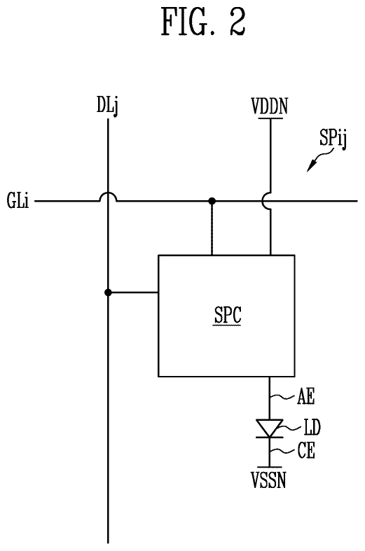

FIG. 2 illustrates a block diagram of one of sub-pixels included in the display device of FIG. 1. In FIG. 2, among the sub-pixels SP of FIG. 1, a sub-pixel SPij disposed in an i-th row (i is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL in FIG. 1 to receive the first power voltage. The second power voltage node VSSN may be connected to another one of the power lines PL in FIG. 1 to receive the second power voltage. The first power voltage may have a higher level than the second power voltage.

The light emitting element LD may be connected between the anode electrode AE and the cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode CE may be connected to the second power voltage node VSSN. The light emitting element LD is configured to emit light according to a current flowing from the anode electrode AE to the cathode electrode CE.

The sub-pixel circuit SPC may be connected to an i-th gate line GLi of the first to m-th gate lines GL1 to GLm of FIG. 1 and a j-th data line DLj of the first to n-th data lines DL1 to DLn of FIG. 1. In response to the gate signal received through the i-th gate line GLi, the sub-pixel circuit SPC controls the light emitting element LD to emit light according to the data signal received through the j-th data line DLj. In embodiments, the sub-pixel circuit SPC may be further connected to the pixel control lines PXCL of FIG. 1. In this case, the sub-pixel circuit SPC may control the light emitting element LD in further response to pixel control signals received through the pixel control lines PXCL.

For these operations, the sub-pixel circuit SPC may include circuit elements, for example transistors and one or more capacitors.

The transistors of the sub-pixel circuit SPC may include P-type transistors and/or N-type transistors. In embodiments, the transistors of the sub-pixel circuit SPC may include a metal oxide semiconductor field effect transistor (MOSFET). In embodiments, the transistors of the sub-pixel circuit SPC may include an amorphous silicon semiconductor, a monocrystalline silicon semiconductor, a polycrystalline silicon semiconductor, and an oxide semiconductor.

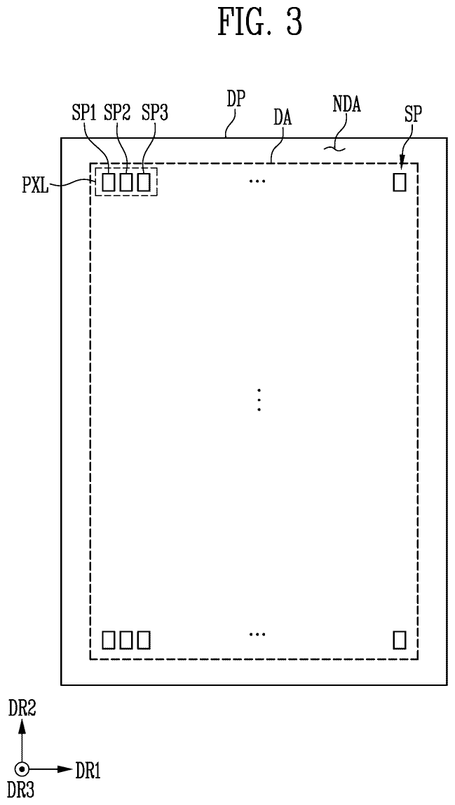

FIG. 3 illustrates a schematic top plan view of a display panel configuring the display device of FIG. 1.

Referring to FIG. 3, the display panel DP may include a display area DA and a non-display area NDA. The display panel DP may display an image through the display area DA. The non-display area NDA may be disposed around the display area DA.

The display panel DP may include sub-pixels SP disposed in the display area DA. The sub-pixels SP may be arranged along a first direction DR1 and a second direction DR2 that intersects the first direction DR1. For example, the sub-pixels SP may be arranged in a matrix format along the first direction DR1 and the second direction DR2. As another example, the sub-pixels SP may be arranged in a zigzag form along first direction DR1 and second direction DR2. The arrangement of the sub-pixels SP may vary in an embodiment. The first direction DR1 may be a row direction, and the second direction DR2 may be a column direction.

Two or more of the sub-pixels SP may configure one pixel PXL. FIG. 3 illustrates that the pixel PXL may include three sub-pixels SP1, SP2, and SP3, but embodiments are not limited thereto. For example, the pixel PXL may include two sub-pixels. Hereinafter, for better understanding and ease of description, it is assumed that the pixel PXL may include the first to third sub-pixels SP1, SP2, and SP3.

Each of the first to third sub-pixels SP1, SP2, and SP3 may generate one of various colors such as red, green, blue, cyan, magenta, and yellow. Hereinafter, for clear and brief description, it is assumed that the first sub-pixel SP1 is configured to generate red-colored light, the second sub-pixel SP2 is configured to generate green-colored light, and the third sub-pixel SP3 is configured to generate blue-colored light.

Each of the first to third sub-pixels SP1, SP2, and SP3 may include at least one light emitting element configured to generate light. In embodiments, the light emitting elements of the first to third sub-pixels SP1, SP2, and SP3 may generate light of the same color. For example, the light emitting elements of the first to third sub-pixels SP1, SP2, and SP3 may generate blue colored light. In embodiments, the light emitting elements of the first to third sub-pixels SP1, SP2, and SP3 may generate light of different colors. For example, the light emitting elements of the first to third sub-pixels SP1, SP2, and SP3 may generate light of red, green, and blue colors, respectively.

As the display panel DP, a self-luminous display panel such as an LED display panel using a micro-scale or nano-scale light emitting diode as a light emitting element and an organic light emitting display panel using an organic light emitting diode as a light emitting element may be used.

A constituent element to control the sub-pixels SP may be disposed in the non-display area NDA. Wires connected to the sub-pixels SP, for example, the first to m-th gate lines GL1 to GLm, the first to n-th data lines DL1 to DLn, the power lines PL, and the pixel control lines PXCL shown in FIG. 1 may be disposed in the non-display area NDA.

At least one of the gate driver 120, the data driver 130, the voltage generator 140, and the controller 150 in FIG. 1 may be disposed in the non-display area NDA of the display panel DP. In embodiments, the gate driver 120 may be disposed in the non-display area NDA. In this case, the data driver 130, the voltage generator 140, and the controller 150 may be implemented as the driver integrated circuit DIC of FIG. 1 separated from the display panel DP, and the driver integrated circuit DIC may be connected to wires disposed in the non-display area NDA. In other embodiments, the gate driver 120 may be implemented as one integrated circuit separated from the display panel DP together with the data driver 130, the voltage generator 140, and the controller 150.

In embodiments, the display area DA may have various shapes. The display area DA may have a closed-loop shape including sides of a straight line and/or a curved line. For example, the display area DA may have shapes such as a polygonal shape, a circular shape, a semicircular, and an elliptical shape.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate of the display panel DP may include materials with flexible properties.

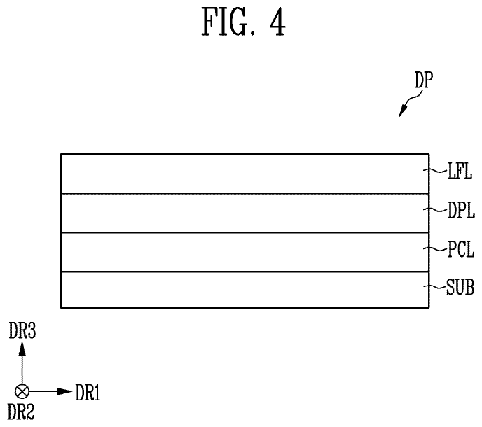

FIG. 4 illustrates a schematic cross-sectional view of the display panel of FIG. 3 according to an embodiment.

Referring to FIG. 4, the display panel DP may include a substrate SUB, and a pixel circuit layer PCL, a display panel layer DPL, and a light functional layer LFL, which are sequentially stacked each other on the substrate SUB in a third direction DR3 crossing (or intersecting) the first and second directions DR1 and DR2.

The substrate SUB may be made of an insulating material such as glass or a resin. For example, the substrate SUB may include a glass substrate. As another example, the substrate SUB may include a polyimide (PI) substrate. As yet another example, the substrate SUB may include a silicon wafer substrate formed using a semiconductor process.

In embodiments, the substrate SUB may be made of a flexible material to be bendable or foldable, and may have a single-layered structure or a multi-layered structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers and semiconductor patterns and conductive patterns disposed between the insulating layers. The conductive patterns of the pixel circuit layer PCL may function as circuit elements, wires, and the like within the spirit and the scope of the disclosure.

The circuit elements of the pixel circuit layer PCL may configure the sub-pixel circuit SPC of each of the sub-pixels SP of FIG. 3. In other words, the circuit elements of the pixel circuit layer PCL may be provided as transistors and one or more capacitors of the sub-pixel circuit SPC.

The wires of the pixel circuit layer PCL may include wires connected to the sub-pixels SP. The wires of the pixel circuit layer PCL may include various signal lines and/or voltage lines required to drive the display panel layer DPL.

The display panel layer DPL may be disposed on the pixel circuit layer PCL. The display panel layer DPL may include light emitting elements of the sub-pixels SP.

The light functional layer LFL may be disposed on the display panel layer DPL. The light functional layer LFL may include light conversion patterns having color conversion particles and/or scattering particles. For example, the color conversion particles may include quantum dots. The quantum dots may change the wavelength (or color) of light emitted from the display panel layer DPL. The light functional layer LFL may further include light scattering patterns with scattering particles. In embodiments, the light conversion patterns and the light scattering patterns may be omitted.

The light functional layer LFL may further include a color filter layer including color filters. The color filter may selectively transmit light of a given wavelength (or a given color). In embodiments, the color filter layer may be omitted.

A window for protecting an exposed surface (or upper surface) of the display panel DP may be provided on the light functional layer LFL. The window may protect the display panel DP from external impact. The window may be coupled or connected to the light functional layer LFL through an optically transparent adhesive (bonding) member. The window may have a multi-layered structure selected from a glass substrate, a plastic film, and a plastic substrate. The multi-layered structure may be formed through a continuous process or an adhesive process using an adhesive layer. All or a portion of the window may be flexible.

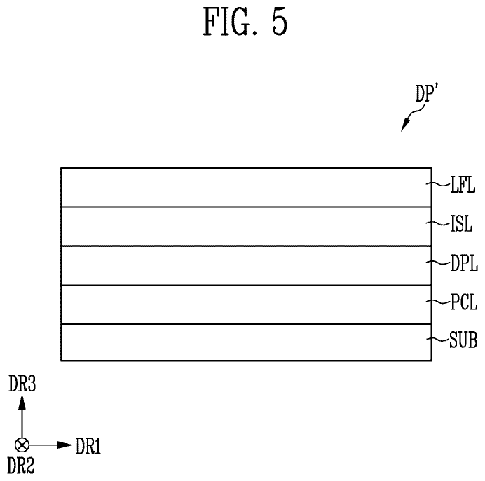

FIG. 5 illustrates a schematic cross-sectional view of the display panel of FIG. 3 according to an embodiment.

Referring to FIG. 5, a display panel DP′ may include a substrate SUB, a pixel circuit layer PCL, a display panel layer DPL, an input sensing layer ISL, and a light functional layer LFL. The substrate SUB, the pixel circuit layer PCL, the display panel layer DPL, and the light functional layer LFL may be configured to be substantially the same as (or similar to) the substrate SUB, the pixel circuit layer PCL, the display panel layer DPL, and the optical function layer LFL described with reference to FIG. 4. Accordingly, descriptions of redundant content may be omitted.

The input sensing layer ISL may detect a user input on an upper surface (or display surface) of the display panel DP′. The input sensing layer ISL may include components suitable for sensing an external object such as a user's hand or pen. For example, the input sensing layer ISL may include touch electrodes.

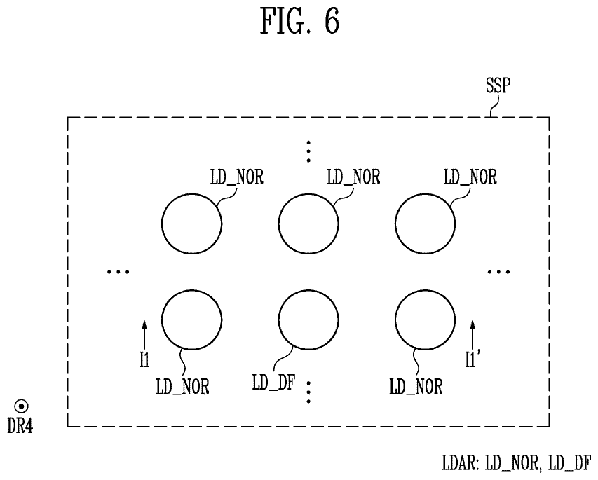

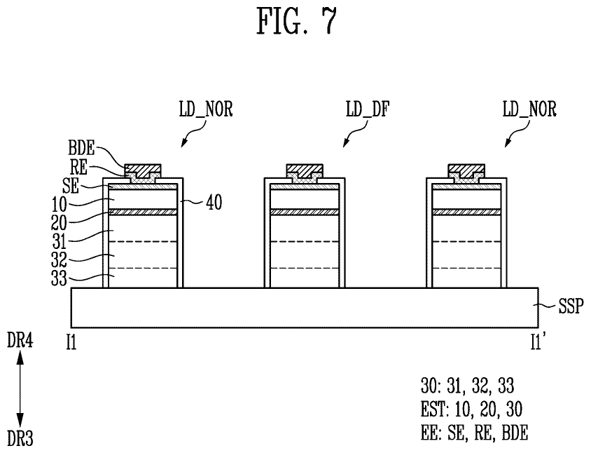

FIG. 6 illustrates a schematic top plan view of a light emitting element array including a plurality of light emitting elements formed on a growth substrate. FIG. 7 illustrates a schematic cross-sectional view taken along line I1-I1′ of FIG. 6.

Referring to FIG. 6 and FIG. 7, a light emitting element array (LDAR) may be formed on a growth substrate SSP. The light emitting element array LDAR may include a plurality of light emitting elements (for example, LD_NOR and LD_DF). There is no limitation to a method of forming the light emitting element array LDAR on the growth substrate SSP, and various known methods may be used. For example, an epitaxial growth process for forming the plurality of light emitting elements may be performed.

The growth substrate SSP may include, for example, a sapphire substrate. However, the material of the growth substrate SSP is not limited thereto. The growth substrate SSP may include various known materials suitable for performing the above-described epitaxial growth process.

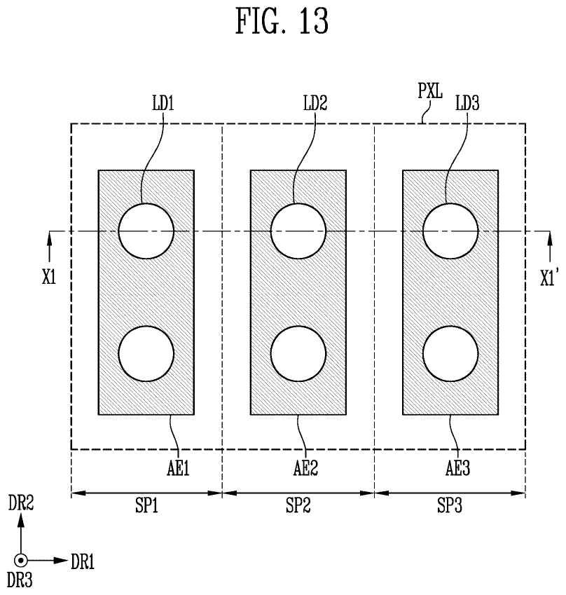

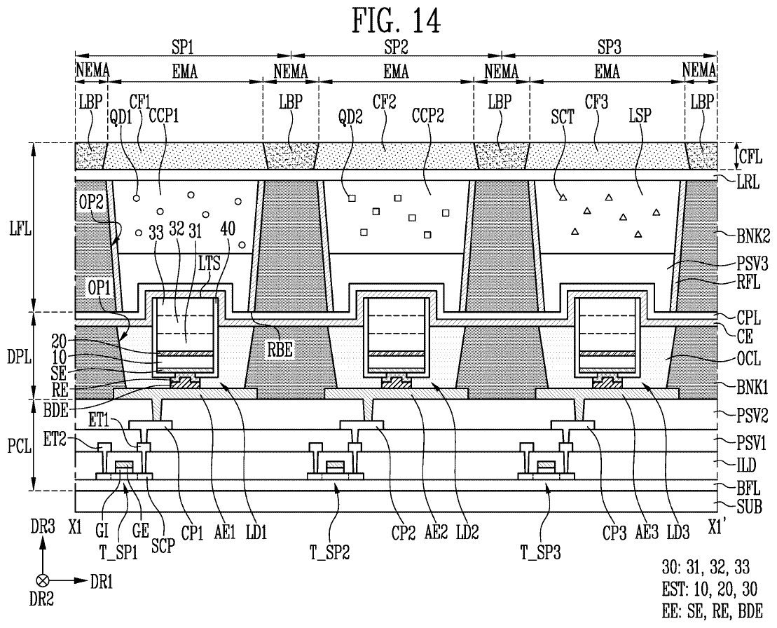

The plurality of light emitting elements included in the light emitting element array LDAR may be disposed on the growth substrate SSP to be spaced apart from each other. One or more of the plurality of light emitting elements may be defective. For example, the plurality of light emitting elements may include a normal light emitting element LD_NOR, and a defective light emitting element LD_DF. The normal light emitting element LD_NOR may be a light emitting element that normally emits light based on an electrical signal provided from a pixel PXL (see FIG. 13 and FIG. 14) to be described later. The defective light emitting element LD_DF may be a light emitting element that does not emit light even in case that an electrical signal is provided. The defective light emitting element LD_DF may be, for example, a light emitting element that has lost its function due to the intervention of foreign substances during the above-described epitaxial process.

The plurality of light emitting elements may be separated from the growth substrate SSP to be provided to the pixel PXL by various known transport devices and methods. A plurality of light emitting elements provided in the pixel PXL may be bonded to electrodes (for example, AE1 to AE3, see FIG. 14). In this case, in case that the defective light emitting element LD_DF is provided and bonded to the pixel PXL, the pixel PXL may not emit light normally. Accordingly, the display quality of the display device DD (see FIG. 1) may deteriorate.

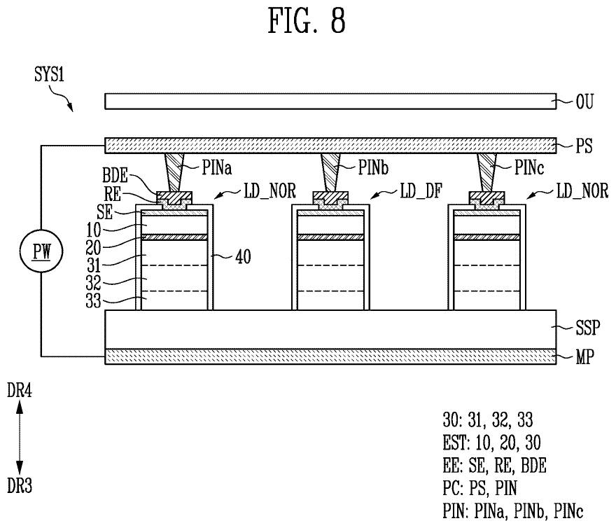

To prevent this, in the disclosure, after forming the light emitting element array LDAR on the growth substrate SSP, a method of performing a lighting test of the plurality of light emitting elements included in the light emitting element array LDAR is provided before the light emitting element array LDAR is separated, transported, and bonded. The lighting test method and the system for performing the lighting test will be described later in detail with reference to FIG. 8 to FIG. 12, and hereinafter, each of the plurality of light emitting elements included in the light emitting element array LDAR will be described in more detail with reference to FIG. 7.

A plurality of light emitting elements included in the light emitting element array LDAR may be configured substantially the same as each other. For example, two normal light emitting elements LD_NOR and one defective light emitting element LD_DF shown in FIG. 7 may be configured substantially the same as each other. Hereinafter, for clear and concise description, a description will be based on the normal light emitting element LD_NOR shown on the left side of FIG. 7.

The normal light emitting element LD_NOR may include a light emitting stack EST, an electrode portion EE, and an insulating film 40.

The light emitting stack EST may include a first semiconductor layer 10, an active layer 20, and a second semiconductor layer 30. The second semiconductor layer 30, active layer 20, and first semiconductor layer 10 may be sequentially stacked each other on the growth substrate SSP along a fourth direction DR4. Here, the fourth direction DR4 may be a direction opposite to the third direction DR3 (see FIG. 3 to FIG. 5). In addition, in describing FIG. 6 to FIG. 12, the fourth direction DR4 may be referred to as an ‘upward direction’.

The first semiconductor layer 10 may be configured to provide holes. The first semiconductor layer 10 may have a first polarity. For example, the first semiconductor layer 10 may include at least one p-type semiconductor layer. For example, the first semiconductor layer 10 may include at least one of gallium nitride (GaN), aluminum gallium nitride (AlGaN), indium gallium nitride (InGaN), aluminum nitride (AlN), and indium nitride (InN), and may be a p-type semiconductor layer doped with a first conductive dopant (or p-type dopant) such as magnesium (Mg), zinc (Zn), calcium (Ca), strontium (Sr), barium (Ba), and the like within the spirit and the scope of the disclosure. However, the material included in the first semiconductor layer 10 is not limited thereto, and the first semiconductor layer 10 may be made of various materials. In the embodiment of the disclosure, the first semiconductor layer 10 may include a gallium nitride (GaN) semiconductor material doped with the first conductive dopant (or p-type dopant).

The active layer 20 may be disposed between the first semiconductor layer 10 and the second semiconductor layer 30 to provide a region in which electrons and holes are recombined. As the electrons and holes are recombined in the active layer 20, they transit to a low energy level, and accordingly, light having a wavelength corresponding thereto may be generated. The active layer 20 may have a single or multiple quantum well structure. In case that the active layer 20 is formed in a multi-quantum well structure, units including a barrier layer, a strain reinforcement layer, and a well layer may be repeatedly stacked each other to form the active layer 20. However, the active layer 20 is not limited to the above-described structure.

The second semiconductor layer 30 may be configured to provide electrons. The second semiconductor layer 30 may have a second polarity different from the first polarity. For example, the second semiconductor layer 30 may include at least one n-type semiconductor layer. For example, the second semiconductor layer 30 may include one of gallium nitride (GaN), aluminum gallium nitride (AlGaN), indium gallium nitride (InGaN), aluminum nitride (AlN), and indium nitride (InN), and may be an n-type semiconductor layer doped with a second conductive dopant (or n-type dopant) such as silicon (Si), germanium (Ge), tin (Sn), and the like within the spirit and the scope of the disclosure. However, the material included in the second semiconductor layer 30 is not limited thereto, and the second semiconductor layer 30 may be formed of various materials. In the embodiment of the disclosure, the second semiconductor layer 30 may include a gallium nitride (GaN) semiconductor material doped with the second conductive dopant (or n-type dopant).

In embodiments, the second semiconductor layer 30 may include a first doped portion 31 disposed below the active layer 20, a second doped portion 32 disposed below the first doped portion 31, and a third doped portion 33 disposed below the second doped portion 32. The first doped portion 31 may be a portion doped with a dopant at a first average doping concentration. The second doped portion 32 may be a portion doped with a dopant at a second average doping concentration lower than the first average doping concentration. The third doped portion 33 may be a portion doped with a dopant at a third average doping concentration lower than the second average doping concentration. The first to third doped portions 31, 32, and 33 may define the second semiconductor layer 30.

In embodiments, the normal light emitting element LD_NOR may be directly formed on the growth substrate SSP. Accordingly, the second semiconductor layer 30 may directly contact the growth substrate SSP. In other words, a lower surface of the second semiconductor layer 30 may directly contact an upper surface of the growth substrate SSP. In this case, other components such as a conductive layer may not be disposed between the second semiconductor layer 30 and the growth substrate SSP.

In embodiments, the light emitting stack EST may have a pillar shape in which the second semiconductor layer 30, the active layer 20, and the first semiconductor layer 10 are sequentially stacked each other along the fourth direction DR4. For example, the light emitting stack EST may have a cylindrical shape, but embodiments are not limited thereto.

The electrode portion EE may be disposed on a light emitting stack EST. The electrode portion EE may include an auxiliary electrode SE, a reflective electrode RE, and a bonding electrode BDE, which are sequentially stacked each other along the fourth direction DR4.

The auxiliary electrode SE may be disposed on the first semiconductor layer 10. The auxiliary electrode SE may be in electrical contact with the first semiconductor layer 10. In embodiments, the auxiliary electrode SE may be configured to be substantially transparent or translucent to satisfy a selectable light transmittance. For example, the auxiliary electrode SE may include a light-transmissive material with conductivity. For example, the auxiliary electrode SE may include at least one of various transparent conductive materials such as an indium tin oxide (ITO), an indium zinc oxide (IZO), a zinc oxide (ZnO), an indium gallium zinc oxide (IGZO), and an indium tin zinc oxide (ITZO). However, the material of the auxiliary electrode SE is not limited thereto.

The reflective electrode RE may be disposed on the auxiliary electrode SE. The reflective electrode RE may be in electrical contact with the auxiliary electrode SE. In embodiments, the reflective electrode RE may include a conductive material having a selectable reflectivity. For example, the reflective electrode RE may include metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. However, the material of the reflective electrode RE is not limited thereto. Since the reflective electrode RE has a selectable reflectance, light emitted from the active layer 20 may be more effectively provided to the light functional layer LFL (see FIG. 14) to be described later.

The bonding electrode BDE may be disposed on the reflective electrode RE. The bonding electrode BDE may be in electrical contact with the reflective electrode RE. In embodiments, the bonding electrode BDE may include a eutectic metal.

In an embodiment, at least one of the auxiliary electrode SE and the reflective electrode RE may be omitted. In case that both the auxiliary electrode SE and the reflective electrode RE are omitted, the bonding electrode BDE may electrically contact the upper surface of the first semiconductor layer 10. In case that one of the auxiliary electrode SE and the reflective electrode RE is omitted, the other electrode may electrically contact the upper surface of the first semiconductor layer 10 and the lower surface of the bonding electrode BDE, respectively.

In embodiments, the auxiliary electrode SE may completely overlap the first semiconductor layer 10. Each of the reflective electrode RE and the bonding electrode BDE may overlap a portion of the first semiconductor layer 10. In other words, the planar area of the auxiliary electrode SE may be substantially the same as the planar area of the first semiconductor layer 10. Each of the planar area of the reflective electrode RE and the planar area of the bonding electrode BDE may be smaller than the planar area of the first semiconductor layer 10.

The insulating film 40 may cover at least a portion of the outer peripheral surface of the light emitting stack EST. For example, the insulating film 40 may cover at least a side surface of the active layer 20. The insulating film 40 may include a transparent insulating material. The insulating film 40 may prevent an electrical short circuit that may occur in case that the active layer 20 comes into contact with another component with conductivity. In embodiments, the insulating film 40 may have a multilayer structure configured of a plurality of layers including a transparent insulating material.

FIG. 8 illustrates a schematic cross-sectional view of a lighting test system for performing a lighting test of the light emitting element array of FIG. 6 according to an embodiment.

Referring to FIG. 8, a lighting test system SYS1 may include a growth substrate SSP, a light emitting element array LDAR, a probe card PC, a conductive plate MP, and an optical test unit OU.

The growth substrate SSP and the light emitting element array LDAR are described as described with reference to FIG. 6 and FIG. 7. Therefore, redundant descriptions thereof may be omitted.

The probe card PC may be disposed on a plurality of light emitting elements LD_NOR and LD_DF included in the light emitting element array LDAR. The probe card PC may be configured to be relatively movable in a direction toward the plurality of light emitting elements LD_NOR and LD_DF. In case that the probe card PC is relatively moved in the direction toward the plurality of light emitting elements LD_NOR and LD_DF, the probe card PC may electrically contact the electrode portions EE of the plurality of light emitting elements LD_NOR and LD DF.

In embodiments, the probe card PC may include a probe substrate PS disposed on the plurality of light emitting elements LD_NOR and LD_DF, and a probe pin PIN protruding in a direction from the probe substrate PS toward the plurality of light emitting elements LD_NOR and LD_DF. A plurality of probe pins PIN may be provided to correspond one-to-one to the plurality of light emitting elements LD_NOR and LD_DF. For example, three probe pins PINa, PINb, and PINc corresponding to the three light emitting elements LD_NOR and LD_DF shown in FIG. 8 may be provided. The probe pin PIN may be a portion that is in electrical contact with the electrode part EE of the plurality of light emitting elements LD_NOR and LD_DF. In this case, the probe substrate PS may be electrically connected to the probe pin PIN.

The conductive plate MP may be disposed below the growth substrate SSP. The conductive plate MP may include a conductive material. For example, the conductive plate MP may include a metal material. The conductive plate MP may be configured to be relatively movable in a direction toward the growth substrate SSP. In case that the conductive plate MP is relatively moved in the direction toward the growth substrate SSP, the conductive plate MP may directly contact the lower surface of the growth substrate SSP.

An electric field may be formed between the probe card PC and the conductive plate MP. For example, the lighting test system SYS1 may further include a power source PW electrically connected to each of the probe card PC and the conductive plate MP. By the power source PW, an electric field may be formed between the probe card PC and the conductive plate MP.

The electric field may be formed in a state in which the probe card PC is in electrical contact with the electrode portion EE, and in a state in which the conductive plate MP is in contact with the lower surface of the growth substrate SSP. In this case, due to the electric field, the normal light emitting element LD_NOR may emit light. However, light may not be emitted from the defective light emitting element LD_DF.

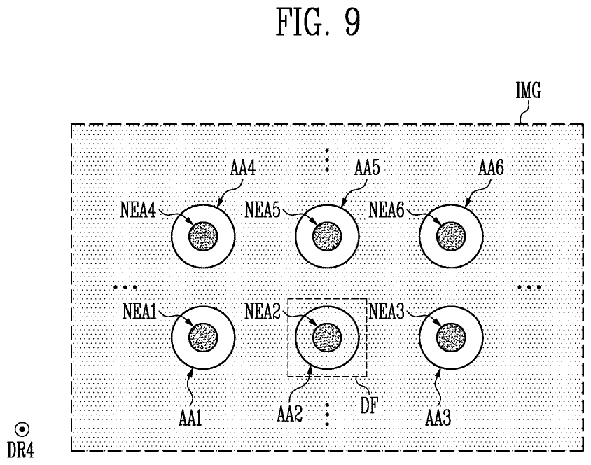

The optical test unit OU may be disposed on the probe card PC. In case that an electric field is formed between the probe card PC and the conductive plate MP, the optical test unit OU may generate an image IMG (see FIG. 9) imaging the plurality of light emitting elements LD_NOR and LD_DF included in the light emitting element array LDAR.

FIG. 9 illustrates a schematic top plan view of an image imaged by an optical test unit included in the lighting test system of FIG. 8.

Referring to FIG. 9, an image IMG of first to sixth areas AA1, AA2, AA3, AA4, AA5, and AA6 corresponding to positions of the plurality of light emitting elements LD_NOR and LD_DF included in the light emitting element array LDAR of FIG. 6 may be formed.

First to sixth non-light emitting areas NEA1, NEA2, NEA3, NEA4, NEA5, and NEA6 may be defined in the centers of the first to sixth areas AA1, AA2, AA3, AA4, AA5, and AA6. The first to sixth non-light emitting areas NEA1, NEA2, NEA3, NEA4, NEA5, and NEA6 may be areas corresponding to the bonding electrode BDE and the reflection electrode RE included in the electrode portion EE of the plurality of light emitting elements LD_NOR and LD_DF.

The first area AA1 and the third to sixth areas AA3, AA4, AA5, and AA6 may be areas in which the normal light emitting element LD_NOR is disposed. Since the first area AA1 and the third to sixth areas AA3, AA4, AA5, and AA6 are areas in which light is emitted, they may be visually recognized as relatively bright areas on the image IMG.

In contrast, the second area AA2 may be an area in which the defective light emitting element LD_DF is disposed. Since the second area AA2 is an area in which light is not emitted, it may be visually recognized as a relatively dark area on the image IMG. Accordingly, based on the image IMG, the defect DF of the defective light emitting element LD_DF disposed in the second area AA2 may be determined.

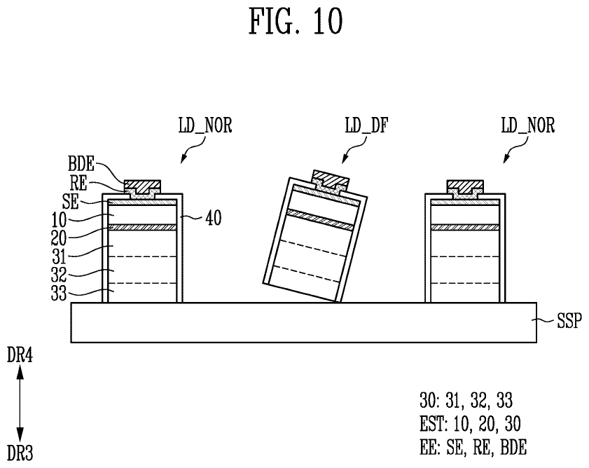

FIG. 10 illustrates a schematic cross-sectional view of an embodiment of removing a light emitting element determined to be defective in lighting based on the image of FIG. 9.

Referring to FIG. 9, the defective light emitting element LD_DF may be removed. Accordingly, only the normal light emitting element LD_NOR may exist on the growth substrate SSP. There is no limitation to a method of removing the defective light emitting element LD_DF, and various known methods may be used. For example, a method of selectively irradiating a laser to the area in which the defective light emitting element LD_DF is disposed may be used.

Referring back to FIG. 8 to FIG. 10, the lighting test method of the disclosure may include forming an electric field between the probe card PC and the conductive plate MP, and testing whether the plurality of light emitting elements included in the light emitting element array LDAR are lighted.

In case that the electric field is formed, the probe card PC may electrically contact the plurality of light emitting elements included in the light emitting element array LDAR. For example, the probe card PC may electrically contact the electrode portion EE electrically contacting the first semiconductor layer 10. In contrast, in case that the electric field is formed, the conductive plate MP may be spaced apart from the plurality of light emitting elements included in the light emitting element array LDAR. For example, the conductive plate MP may be in non-contact with the second semiconductor layer 30. The growth substrate SSP may be disposed between the conductive plate MP and the second semiconductor layer 30, and the conductive plate MP may contact the lower surface of the growth substrate SSP.

As such, even if the conductive plate MP does not directly contact the second semiconductor layer 30, the normal light emitting element LD_NOR among the plurality of light emitting elements included in the light emitting element array LDAR may emit light by the formation of the electric field. For example, even if the light emitting element array LDAR is not separated from the growth substrate SSP, it may be possible to test whether the light emitting element array LDAR is lighted.

The test of whether to be lighted may be performed by testing whether areas corresponding to the plurality of light emitting elements in the image IMG are emitted based on the image IMG obtained by the optical test unit OU.

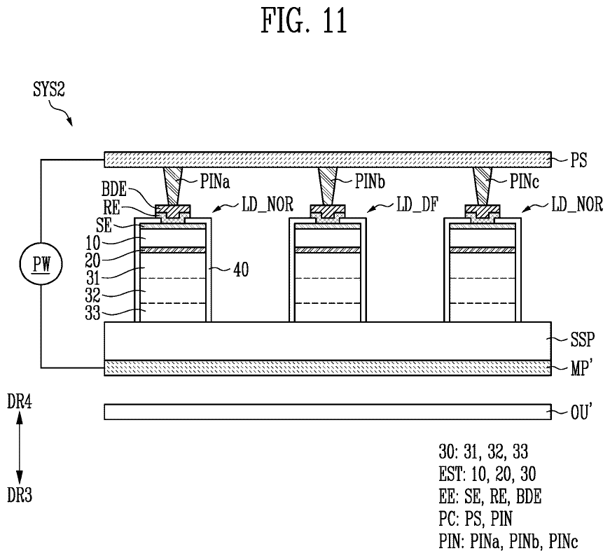

FIG. 11 illustrates a schematic cross-sectional view of a lighting test system for performing a lighting test of the light emitting element array of FIG. 6 according to an embodiment.

Hereinafter, the description will focus on the differences between a lighting test system SYS2 and the lighting test system SYS1 described with reference to FIG. 8, and the omitted description will be replaced with the previous content.

Referring to FIG. 11, the lighting test system SYS2 may include a growth substrate SSP, a light emitting element array LDAR, a probe card PC, a conductive plate MP′, and an optical test unit OU′.

The conductive plate MP′ may be configured to be substantially transparent or translucent to satisfy a selectable light transmittance. For example, the conductive plate MP′ may include a light-transmissive material with conductivity. For example, the conductive plate MP′ may include at least one of various transparent conductive materials such as an indium tin oxide (ITO), an indium zinc oxide (IZO), a zinc oxide (ZnO), an indium gallium zinc oxide (IGZO), and an indium tin zinc oxide (ITZO). However, the material of the conductive plate MP′ is not limited thereto.

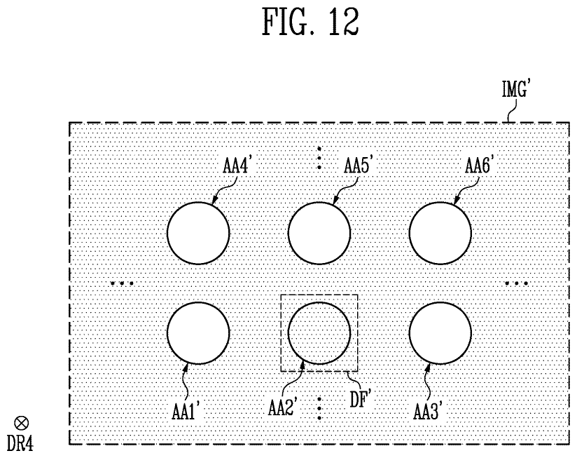

The optical test unit QU′ may be disposed below the conductive plate MP′. In case that an electric field is formed between the probe card PC and the conductive plate MP′, the optical test unit QU′ may generate an image IMG′ (see FIG. 12) imaging the plurality of light emitting elements LD_NOR and LD_DF included in the light emitting element array LDAR.

FIG. 12 illustrates a schematic top plan view of an image imaged by an optical test unit included in the lighting test system of FIG. 11.

Referring to FIG. 12, an image IMG′ of first to sixth areas AA1′, AA2′, AA3′, AA4′, AA5′, and AA6′ corresponding to positions of the plurality of light emitting elements LD_NOR and LD_DF included in the light emitting element array LDAR of FIG. 6 may be formed.

In this case, since the optical test unit OU′ (see FIG. 11) generates images of a plurality of light emitting elements LD_NOR and LD_DF below the conductive plate MP′, the first to sixth non-light emitting areas NEA1, NEA2, NEA3, NEA4, NEA5, and NEA6 described with reference to FIG. 9 may not be defined.

The first area AA1′ and the third to sixth areas AA3′, AA4′, AA5′, and AA6′ may be areas in which the normal light emitting element LD_NOR is disposed. Since the first area AA1′ and the third to sixth areas AA3′, AA4′, AA5′, AA6′ are areas in which light is emitted, they may be visually recognized as relatively bright areas on the image IMG.

In contrast, the second area AA2′ may be an area in which the defective light emitting element LD_DF is disposed. Since the second area AA2′ is an area in which light is not emitted, it may be visually recognized as a relatively dark area on the image IMG′. Accordingly, based on the image IMG′, the defect DF′ of the defective light emitting element LD_DF disposed in the second area AA2′ may be determined.

FIG. 13 illustrates a schematic top plan view of one of pixels of FIG. 3 according to an embodiment.

Referring to FIG. 13, the pixel PXL may include the first to third sub-pixels SP1, SP2, and SP3. The first and third sub-pixels SP1, SP2, and SP3 may be disposed in the first direction DR1. However, the arrangement of pixels PXL is not limited thereto, and may be variously changed in an embodiment. For example, the first to third sub-pixels SP1, SP2, and SP3 may be disposed in a zigzag pattern.

First to third anode electrodes AE1, AE2, and AE3 may be disposed in the first to third sub-pixels SP1, SP2, and SP3, respectively. The first anode electrode AE1 may be provided as the anode electrode AE included in the sub-pixel circuit SPC (see FIG. 2) of the first sub-pixel SP1. The second anode electrode AE2 may be provided as the anode electrode AE included in the sub-pixel circuit SPC of the second sub-pixel SP2. The third anode electrode AE3 may be provided as the anode electrode AE included in the sub-pixel circuit SPC of the third sub-pixel SP3.

One or more first light emitting elements LD1, one or more second light emitting elements LD2, and one or more third light emitting elements LD3 may be disposed on the first to third anode electrodes AE1, AE2, and AE3. The first light emitting elements LD1 may be connected to the first anode electrode AE1. The second light emitting elements LD2 may be connected to the second anode electrode AE2. The third light emitting elements LD3 may be connected to the third anode electrode AE3. In case that a plurality of light emitting elements are provided to each sub-pixel, each anode electrode may have a shape extending in a given direction such as the second direction DR2, and light emitting elements connected thereto may be disposed in the same direction.

The first light emitting elements LD1 may be provided as the light emitting element LD (see FIG. 2) included in the first sub-pixel SP1. The second light emitting elements LD2 may be provided as the light emitting element LD (see FIG. 2) included in the second sub-pixel SP2. The third light emitting elements LD3 may be provided as the light emitting element LD (see FIG. 2) included in the third sub-pixel SP3. In case that a plurality of light emitting elements are provided in one sub-pixel, the plurality of light emitting elements may be connected in parallel between the anode electrode and the cathode electrode to be provided as the light emitting element LD of FIG. 2.

Each of the first light emitting elements LD1, the second light emitting elements LD2, and the third light emitting elements LD3 may be configured to be substantially the same as the normal light emitting element LD_NOR described with reference to FIG. 7.

FIG. 14 illustrates a schematic cross-sectional view taken along line X1-X1′ of FIG. 13.

Referring to FIG. 13 and FIG. 14, the pixel circuit layer PCL, the display panel layer DPL, and the light functional layer LFL may be sequentially disposed on the substrate SUB.

The pixel circuit layer PCL may include insulating layers, semiconductor patterns, and conductive patterns stacked each other on the substrate SUB. The insulating layers may include a buffer layer BFL, one or more interlayer insulating layers ILD, and one or more passivation layers PSV1 and PSV2. The semiconductor patterns and the conductive patterns may be disposed between the insulating layers. The conductive patterns may include at least one of copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (see FIG. 2) DP2 (or of the first to third sub-pixels SP1, SP2, and SP3 may include transistors and one or more capacitors. The semiconductor patterns and conductive patterns of the pixel circuit layer PCL may function as transistors and capacitors of the sub-pixel circuit SPC. The conductive patterns of the pixel circuit layer PCL may further function as wires, for example, the first to m-th gate lines GL1 to GLm, the first to n-th data lines DL1 to DLn, the power lines PL, and the pixel control lines PXLC in FIG. 1.

The buffer layer BFL may be disposed on one surface or a surface of the substrate SUB. The buffer layer BFL may prevent impurities from diffusing into the circuit elements and wires included in the pixel circuit layer PCL. The buffer layer BFL may include an inorganic insulating layer including an inorganic material. In embodiments, the buffer layer BFL may include at least one of metal oxides such as a silicon nitride, a silicon oxide, a silicon oxynitride, and an aluminum oxide. The buffer layer BFL may be provided as a single layer or multiple layers. In case that the buffer layer BFL is provided as the multiple layers, respective layers thereof may be made of the same material or different materials.

In embodiments, one or more barrier layers may be disposed between the substrate SUB and the buffer layer BFL. Each of the barrier layers may include polyimide.

First to third transistors T_SP1, T_SP2, and T_SP3 corresponding to the first to third sub-pixels SP1, SP2, and SP3, respectively, may be disposed on the buffer layer BFL. The first transistor T_SP1 may be one of the transistors of the sub-pixel circuit SPC included in the first sub-pixel SP1. The second transistor T_SP2 may be one of the transistors of the sub-pixel circuit SPC included in the second sub-pixel SP2. The third transistor T_SP3 may be one of the transistors of the sub-pixel circuit SPC included in the third sub-pixel SP3. Each of the first to third transistors T_SP1, T_SP2, and T_SP3 may be understood as a transistor connected to an anode electrode among transistors of a corresponding sub-pixel.

The first transistor T_SP1 may include a semiconductor pattern SCP, a gate electrode GE, a first terminal ET1, and a second terminal ET2. The first terminal ET1 may be one of a source electrode and a drain electrode, and the second terminal ET2 may be the other of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact area in contact with the first terminal ET1 and a second contact area in contact with the second terminal ET2. An area between the first contact area and the second contact area may be a channel area. The channel area may overlap the gate electrode GE of the first transistor T_SP1. The channel area is a semiconductor pattern that is not substantially doped with impurities, and may be an intrinsic semiconductor. The first contact area and the second contact area may be semiconductor patterns doped with impurities. As the impurities, for example, p-type impurities may be used, but embodiments are not limited thereto.

The semiconductor pattern SCP may include one of various types of semiconductors, for example, one of an amorphous silicon semiconductor, a monocrystalline silicon semiconductor, a polycrystalline silicon semiconductor, a low temperature polysilicon semiconductor, and an oxide semiconductor.

Interlayer insulating layers ILD sequentially stacked each other on the semiconductor pattern SCP may be disposed. The interlayer insulating layers ILD may be inorganic insulating layers including an inorganic material. For example, each of the interlayer insulating layers ILD may include at least one of metal oxides such as a silicon nitride, a silicon oxide, a silicon oxynitride, and an aluminum oxide. However, the interlayer insulating layers ILD are not limited thereto. For example, one of the interlayer insulating layers ILD may include an organic insulating layer including an organic material.

The interlayer insulating layers ILD may electrically separate conductive patterns and/or semiconductor patterns disposed between the interlayer insulating layers ILD from each other. For example, the interlayer insulating layers ILD may include a gate insulating layer GI disposed on the semiconductor pattern SCP. The gate insulating layer GI may be disposed between the semiconductor pattern SCP and the gate electrode GE so that the semiconductor pattern SCP is spaced apart from the gate electrode GE. In embodiments, the gate insulating layer GI may be entirely provided on the semiconductor pattern SCP and the buffer layer BFL to cover the semiconductor pattern SCP and the buffer layer BFL. As the number of layers required to form conductive patterns and/or semiconductor patterns increases, the number of the interlayer insulating layers ILD may increase.

The gate electrode GE may be disposed on the gate insulating layer GI. The gate electrode GE may overlap the channel area of the semiconductor pattern SCP. In embodiments, the gate electrode GE may be provided as a single layer including at least one of copper (Cu), molybdenum (Mo), tungsten (W), aluminum neodymium (AlNd), titanium (Ti), aluminum (Al), and silver (Ag). In embodiments, the gate electrode GE may be provided as a multilayer including at least one of molybdenum (Mo), titanium (Ti), copper (Cu), aluminum (Al), and silver (Ag), which are low-resistance materials.

The first and second terminals ET1 and ET2 may be disposed on the interlayer insulating layers ILD. The first and second terminals ET1 and ET2 may contact the semiconductor pattern SCP through contact holes penetrating the interlayer insulating layers ILD. The first and second terminals ET1 and ET2 may contact the first and second contact areas of the semiconductor pattern SCP, respectively. Each of the first and second terminals ET1 and ET2 may include at least one of copper (Cu), molybdenum (Mo), tungsten (W), aluminum neodymium (AlNd), titanium (Ti), aluminum (Al), and silver (Ag).

Although the first and second terminals ET1 and ET2 are illustrated as separate electrodes electrically connected to the semiconductor pattern SCP, the embodiments are not limited thereto. In embodiments, the first terminal ET1 may be a first contact area adjacent to one side or a side of the channel area of the semiconductor pattern SCP, and the second terminal ET2 may be a second contact area adjacent to the other side of the channel area thereof. In this case, the first terminal ET1 may be electrically connected to the light emitting element LD through a connection member such as a bridge electrode disposed on at least one of the interlayer insulating layers ILD.

In embodiments, the first transistor T_SP1 may be configured as a low-temperature polysilicon transistor. However, embodiments are not limited thereto. For example, the first transistor T_SP1 may be configured as an oxide semiconductor transistor. In embodiments, the sub-pixel circuit of each sub-pixel may include different types of transistors. For example, the first transistor T_SP1 may be configured as a low-temperature polysilicon transistor, and another transistor included in the sub-pixel circuit SPC of the first sub-pixel SP1 may be configured as an oxide semiconductor transistor. In this case, the oxide semiconductor of the corresponding oxide semiconductor transistor may be disposed on one of the interlayer insulating layers ILD, rather than the insulating layer in which the semiconductor pattern SCP of the first transistor T_SP1 is disposed.

In the embodiments, the case in which the first transistor T_SP1 is a transistor with a top gate structure has been described as an example, but the embodiments are not limited thereto. For example, the first transistor T_SP1 may be a transistor with a bottom gate structure. The structure of the first transistor T_SP1 may be variously changed.

Each of the second and third transistors T_SP2 and T_SP3 may be configured similarly to the first transistor T_SP1. Accordingly, descriptions of redundant content may be omitted.

At least some of the various wires of the display panel DP and/or the display device DD may be further disposed on the interlayer insulating layers ILD.

A first passivation layer PSV1 may be disposed on the interlayer insulating layers ILD and the first and second terminals ET1, and ET2. The passivation layer may also be referred to as a protective layer or via layer. The first passivation layer PSV1 may protect components disposed below the first passivation layer PSV1 and may provide a flat upper surface.

First to third connection patterns CP1, CP2, and CP3 may be disposed on the first passivation layer PSV1. The first to third connection patterns CP1, CP2, and CP3 may penetrate the first passivation layer PSV1 to be connected to the first terminals ET1 of the first to third transistors T_SP1, T_SP2, and T_SP3, respectively. The first to third connection patterns CP1, CP2, and CP3 may include at least one of copper (Cu), molybdenum (Mo), tungsten (W), aluminum neodymium (AlNd), titanium (Ti), aluminum (Al), and silver (Ag).

At least some of the various wires of the display panel DP and/or the display device DD may be further disposed on the first passivation layer PSV1.

A second passivation layer PSV2 may be disposed on the first to third connection patterns CP1, CP2, and CP3 and the first passivation layer PSV1. The second passivation layer PSV2 may protect components disposed below the second passivation layer PSV2 and may provide a flat upper surface.

Each of the first and second passivation layers PSV1 and PSV2 may include an inorganic insulating layer including an inorganic material and/or an organic insulating layer including an organic material. The inorganic insulating layer may include, for example, at least one of metal oxides such as a silicon oxide, a silicon nitride, a silicon oxynitride, and an aluminum oxide. The organic insulating layer may include at least one of, for example, an acrylic resin, an epoxy resin, a phenol resin, a polyamide resin, a polyimide resin, an unsaturated polyester resin, a poly-phenylene ether resin, a poly-phenylene sulfide resin, and a benzocyclobutene resin.

The first and second passivation layers PSV1 and PSV2 may include the same material as one of the interlayer insulating layers ILD, but embodiments are not limited thereto. Each of the first and second passivation layers PSV1 and PSV2 may be provided as a single layer, but may be provided as a multilayer.

The display panel layer DPL may be disposed on the second passivation layer PSV2. The display panel layer DPL may include the first to third anode electrodes AE1, AE2, and AE3, the first bank BNK1, the first to third light emitting elements LD1, LD2, and LD3, the overcoat layer OCL, the cathode electrode CE, and the capping layer CPL.

On the pixel circuit layer PCL, the first to third anode electrodes AE1, AE2, and AE3 may be disposed in the first to third sub-pixels SP1, SP2, and SP3, respectively.

The first anode electrode AE1 may be electrically connected to the first connection pattern CP1 through a contact hole penetrating the second passivation layer PSV2. The second anode electrode AE2 may be electrically connected to the second connection pattern CP2 through another contact hole penetrating the second passivation layer PSV2. The third anode electrode AE3 may be electrically connected to the third connection pattern CP3 through another contact hole penetrating the second passivation layer PSV2. As such, the first to third anode electrodes AE1, AE2, and AE3 may be electrically connected to the first to third transistors T_SP1, T_SP2, and T_SP3, respectively.

The first bank BNK1 may be disposed on the first to third anode electrodes AE1, AE2, and AE3. The first bank BNK1 may have first openings OP1 exposing portions of the first to third anode electrodes AE1, AE2, and AE3. The first to third light emitting elements LD1, LD2, and LD3 may be disposed in the first openings OP1 of the first bank BNK1. As such, the first bank BNK1 may be provided as a pixel defining film that defines an area in which the first to third light emitting elements LD1, LD2, and LD3 are disposed.

The first bank BNK1 is configured to include a light-blocking material, thereby preventing light mixing between adjacent sub-pixels. In embodiments, the first bank BNK1 may include an organic material. For example, the first bank BNK1 may include an organic insulating material such as an acrylic resin, an epoxy resin, a phenol resin, a polyamide resin, a polyimide resin, or the like within the spirit and the scope of the disclosure. In an embodiment, in order to further improve light output efficiency, a reflective layer including a reflective material may be further disposed on the side surface of the first bank BNK1 adjacent to the first openings OP1.

The first to third light emitting elements LD1, LD2, and LD3 may be disposed on the first to third anode electrodes AE1, AE2, and AE3, respectively. The first to third light emitting elements LD1, LD2, and LD3 may be bonded and coupled or connected to the first to third anode electrodes AE1, AE2, and AE3, respectively. The first to third light emitting elements LD1, LD2, and LD3 may be configured to be substantially the same as the normal light emitting element LD_NOR described with reference to FIG. 7. Accordingly, descriptions of redundant content may be omitted.

The bonding electrode BDE of the first light emitting element LD1 may be connected to the first anode electrode AE1. The bonding electrode of the second light emitting element LD2 may be connected to the second anode electrode AE2. The bonding electrode of the third light emitting element LD3 may be connected to the third anode electrode AE3. Upper surfaces of the second semiconductor layers 30 of the first to third light emitting elements LD1, LD2, and LD3 may be connected to the cathode electrode CE. Accordingly, the first light emitting element LD1 may be connected between the first anode electrode AE1 and the cathode electrode CE, the second light emitting element LD2 may be connected between the second anode electrode AE2 and the cathode electrode CE, and the third light emitting element LD3 may be connected between the third anode electrode AE3 and the cathode electrode CE.

The overcoat layer OCL may be disposed in the first openings OP1 in which the first to third light emitting elements LD1, LD2, and LD3 are disposed. The overcoat layer OCL may fix the first to third light emitting elements LD1, LD2, and LD3 bonded to the first to third anode electrodes AE1, AE2, and AE3 so as not to move. The overcoat layer OCL may protect components disposed below the overcoat layer OCL from foreign substances such as dust and moisture. The overcoat layer OCL may include at least one of an inorganic insulating layer and an organic insulating layer. For example, the overcoat layer OCL may include epoxy, but embodiments are not limited thereto.

In embodiments, the overcoat layer OCL may not be disposed on the upper surfaces of the first to third light emitting elements LD1, LD2, and LD3. The first to third light emitting elements LD1, LD2, and LD3 may protrude into the light functional layer LFL. The first to third light emitting elements LD1, LD2, and LD3 may be disposed at least partially in the second openings OP2 of the second bank BNK2. For example, a height of an upper surface LTS of each of the first to third light emitting elements LD1, LD2, and LD3 from the substrate SUB may be higher than the lowermost end RBE of the reflective layer RFL. Accordingly, the light emitted from the first to third light emitting elements LD1, LD2, and LD3 may be provided to the light functional layer LFL at a relatively high ratio.

The cathode electrode CE may be disposed on the first to third light emitting elements LD1, LD2, and LD3. The cathode electrode CE may be entirely disposed on the first bank BNK1, the first to third light emitting elements LD1, LD2, and LD3, and the overcoat layer OCL. The cathode electrode CE may contact the upper surface of the second semiconductor layer 30 of each of the first to third light emitting elements LD1, LD2, and LD3. The cathode electrode CE may be electrically connected to the second power voltage node VSSN of FIG. 2. The second power voltage applied to the second power voltage node VSSN may be transmitted to the first to third light emitting elements LD1, LD2, and LD3 through the cathode electrode CE.

The cathode electrode CE may be configured to be substantially transparent or translucent to satisfy a selectable light transmittance. In embodiments, the cathode electrode CE may include at least one of various transparent conductive materials such as an indium tin oxide (ITO), an indium zinc oxide (IZO), a zinc oxide (ZnO), an indium gallium zinc oxide (IGZO), and an indium tin zinc oxide (ITZO). However, the material of the cathode electrode CE is not limited thereto.

The capping layer CPL may be disposed on the cathode electrode CE. The capping layer CPL may protect components below the capping layer CPL, such as the cathode electrode CE and the first to third light emitting elements LD1, LD2, and LD3, from external moisture and moisture. The capping layer CPL may include at least one of metal oxides such as a silicon nitride, a silicon oxide, a silicon oxynitride, and an aluminum oxide. However, the material of the capping layer CPL is not limited thereto.

The light functional layer LFL may be disposed on the capping layer CPL. The light functional layer LFL may include a second bank BNK2, a reflective layer RFL, a third passivation layer PSV3, first and second light conversion patterns CCP1 and CCP2, a light scattering pattern LSP, a low refractive index layer LRL, and a color filter layer CFL.

The second bank BNK2 may be disposed on the capping layer CPL. The second bank BNK2 may overlap the first bank BNK1. The second bank BNK2 may have second openings OP2 that overlap the first openings OP1.

The second bank BNK2 may be configured to include a light blocking material to prevent light mixing between adjacent pixels and the first to third sub-pixels SP1, SP2, and SP3. In embodiments, the second bank BNK2 may include an organic material. For example, the second bank BNK2 may include an organic insulating material such as an acrylic resin, an epoxy resin, a phenol resin, a polyamide resin, a polyimide resin, or the like within the spirit and the scope of the disclosure.

The reflective layer RFL may be disposed on side surfaces of the second bank BNK2 adjacent to the second openings OP2. The reflective layer RFL is configured to reflect incident light, thereby improving outgoing light efficiency. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom. However, embodiments are not limited thereto.

It may be understood that the light emitting area EMA and the non-light emitting area NEMA for the first to third sub-pixels SP1, SP2, and SP3 are defined by the second bank BNK2. An area where the second bank BNK2 overlaps may correspond to the non-light emitting area NEMA. An area overlapping the second openings OP2 of the second bank BNK2 may correspond to the light emitting area EMA.

On the capping layer CPL, the third passivation layer PSV3 may be disposed in the second openings OP2. The third passivation layer PSV3 may protect components disposed below the third passivation layer PSV3 and may provide a flat upper surface. The third passivation layer PSV3 may include the same material as one of the first and second passivation layers PSV1 and PSV2, but embodiments are not limited thereto.

On the third passivation layer PSV3, the first and second light conversion patterns CCP1 and CCP2 and the light scattering pattern LSP may be disposed in the second openings OP2.

The first and second light conversion patterns CCP1 and CCP2 and the light scattering pattern LSP may include color conversion particles and/or scattering particles. The color conversion particles may convert incident light into light of a different color by changing the wavelength of the incident light. The color conversion particles may scatter incident light. In embodiments, the color conversion particles may be quantum dots. The scattering particles may scatter incident light.

In embodiments, the first to third light emitting elements LD1, LD2, and LD3 may be configured to emit blue-colored light. In this case, the first light conversion pattern CCP1 may include first color conversion particles QD1 configured to convert blue-colored light into red-colored light. The second light conversion pattern CCP2 may include second color conversion particles QD2 configured to convert blue-colored light into green-colored light. The light scattering pattern LSP may include scattering particles SCT that scatter blue-colored light in order to improve light output efficiency. Accordingly, the first to third sub-pixels SP1, SP2, and SP3 may be provided as a red sub-pixel, a green sub-pixel, and a blue sub-pixel, respectively. In embodiments, at least one of the first and second light conversion patterns CCP1 and CCP2 and the light scattering pattern LSP may further include color conversion particles that convert blue-colored light into white-colored light.

In embodiments, the first to third light emitting elements LD1, LD2, and LD3 may be configured to emit red-colored light, green-colored light, and blue-colored light, respectively. In this case, each of the first and second light conversion patterns CCP1 and CCP2 and the light scattering pattern LSP may include the scattering particles SCT. As described above, the particles included in the first and second light conversion patterns CCP1 and CCP2 and the light scattering pattern LSP may be variously changed according to the color of the light emitted from the first to third light emitting elements LD1, LD2, and LD3.

In embodiments, the first and second light conversion patterns CCP1 and CCP2 and the light scattering pattern LSP may be omitted.

A low refractive index layer LRL may be disposed on the second bank BNK2, the reflective layer RFL, the first and second light conversion patterns CCP1 and CCP2, and the light scattering pattern LSP. The low refractive index layer LRL may have a lower refractive index than that of the first and second light conversion patterns CCP1 and CCP2 and the light scattering pattern LSP. The low refractive index layer LRL may be configured to refract or totally reflect the corresponding light according to an incident angle of the light. The low refractive index layer LRL may provide light passing through the first and second light conversion patterns CCP1 and CCP2 and the light scattering pattern LSP back to the first and second light conversion patterns CCP1 and CCP2 and the light scattering pattern LSP. Accordingly, light conversion efficiency and light scattering efficiency of the first and second light conversion patterns CCP1 and CCP2 and the light scattering pattern LSP may be improved. In embodiments, the low refractive index layer LRL may be omitted in an area corresponding to the third sub-pixel SP3.

The color filter layer CFL may be disposed on the low refractive index layer LRL. The color filter layer CFL may include first to third color filters CF1, CF2, and CF3 and light blocking patterns LBP.

The first to third color filters CF1, CF2, and CF3 may overlap the first and second light conversion patterns CCP1 and CCP2 and the light scattering patterns LSP, respectively. Each of the first to third color filters CF1, CF2, and CF3 may selectively transmit light in a desired wavelength range. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter. The first to third color filters CF1, CF2, and CF3 may have a higher refractive index than the low refractive index layer LRL. However, embodiments are not limited thereto, and the first to third color filters CF1, CF2, and CF3 may have a refractive index lower than or equal to that of the low refractive index layer LRL.

The light blocking patterns LBP may be disposed between the first to third color filters CF1, CF2, and CF3. It may be understood that the light emitting area EMA and the non-light emitting area NEMA for the first to third sub-pixels SP1, SP2, and SP3 are defined by the light blocking patterns LBP. An area overlapping the light blocking patterns LBP may correspond to the non-light emitting area NEMA. An area that does not overlap the light blocking patterns LBP may correspond to the light emitting area EMA.

In embodiments, the light blocking patterns LBP may include at least one of various types of light blocking materials. In embodiments, each of the light blocking patterns LBP may be provided in the form of a multilayer in which at least two of the first to third color filters CF1, CF2, and CF3 overlap. For example, each of the light blocking patterns LBP may be formed by overlapping the first to third color filters CF1, CF2, and CF3. As another example, among of the light blocking patterns LBP, a light blocking pattern between the first and second color filters CF1 and CF2 may be formed as a multilayer in which the first and second color filters CF1 and CF2 overlap, and among of the light blocking patterns LBP, a light blocking pattern between the second and third color filters CF2 and CF3 may be formed as a multilayer in which the second and third color filters CF2 and CF3 overlap. The light blocking pattern between the first color filter CF1 and the third color filter CF3 of a neighboring pixel may be formed as a multilayer in which the first and third color filters CF1 and CF3 overlap. In this way, each of the first to third color filters CF1, CF2, and CF3 may extend to the non-light emitting area NEMA to form the light blocking patterns LBP.

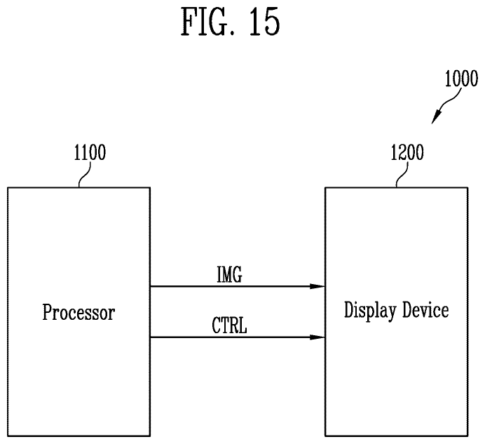

FIG. 15 illustrates a block diagram of a display system according to an embodiment.

Referring to FIG. 15, a display system 1000 may include a processor 1100 and a display device 1200.

The processor 1100 may perform various tasks and calculations. In embodiments, the processor 1100 may include an application processor, a graphics processor, a microprocessor, a central processing unit (CPU), and the like within the spirit and the scope of the disclosure. The processor 1100 may be connected to and step other constituent elements of the display system 1000 through a bus system.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. In this case, the image data IMG and the control signal CTRL may be provided as the input image data IMG and the control signal CTRL of FIG. 1, respectively.

The display system 1000 may include a computing system that provides image display functions such as a smart watch, a mobile phone, a smart phone, a portable computer, a tablet personal computer (PC), a watch phone, an automatic display, a smart glass, a portable multimedia layer (PMP), a navigation system, and an ultra mobile personal computer (UMPC). The display system 1000 may include at least one of a head-mounted display device (HMD), a virtual reality (VR) device, a mixed reality (MR) device, and an augmented reality (AR) device.

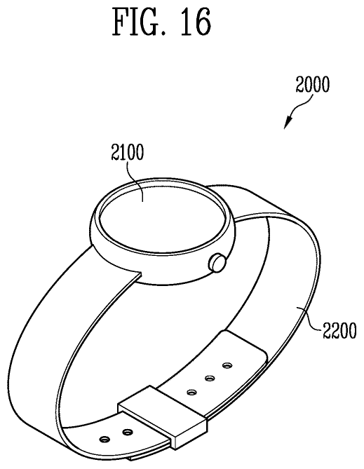

FIG. 16 to FIG. 19 illustrate schematic perspective views of application examples of the display system of FIG. 15.

Referring to FIG. 16, the display system 1000 of FIG. 15 may be applied to a smart watch 2000 including a display portion 2100 and a strap portion 2200.

The smart watch 2000 may be a wearable electronic device. For example, the smart watch 2000 may have a structure in which the strap portion 2200 is mounted on the user's wrist. Here, the display system 1000 and/or the display device 1200 may be applied to the display portion 2100, so that image data including time information may be provided to the user.

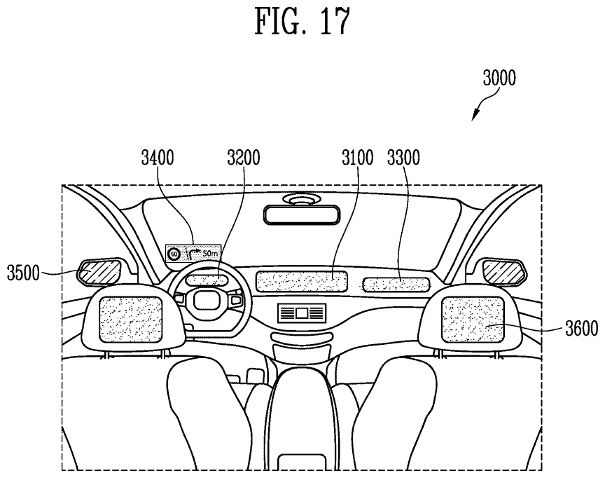

Referring to FIG. 17, the display system 1000 of FIG. 15 may be applied to an automotive display system 3000. Here, the automotive display system 3000 may include a computing system that is provided inside and/or outside the vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear-seat display 3600, which are provided in the vehicle.

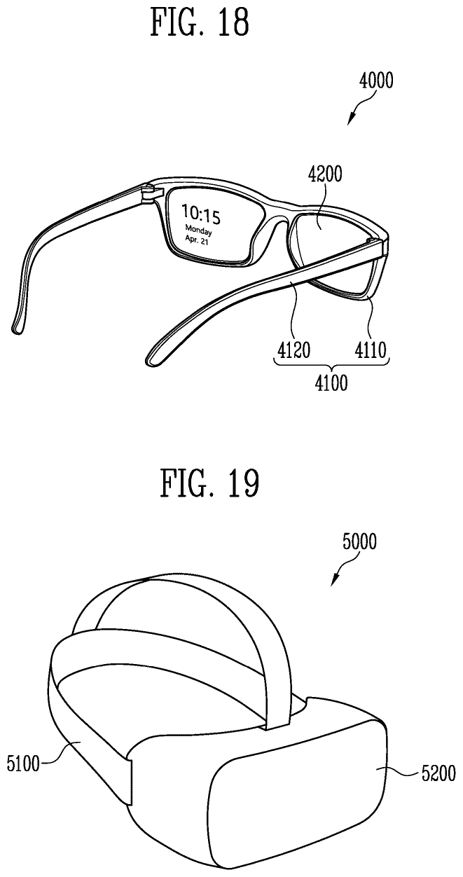

Referring to FIG. 18, the display system 1000 of FIG. 15 may be applied to smart glasses 4000. The smart glasses 4000 may be a wearable electronic device that may be worn on the user's head. For example, the smart glasses 4000 may be a wearable device for augmented reality.

The smart glasses 4000 may include a frame 4100 and a lens portion 4200. The frame 4100 may include a housing 4110 supporting the lens portion 4200 and a leg portion 4120 for the user to wear. The leg portion 4120 may be connected to the housing 4110 through a hinge to be folded or unfolded with respect to the housing 4110.

A battery, a touch pad, a microphone, and a camera may be embedded in the frame 4100. In addition, a projector that outputs light and a processor that controls an optical signal and the like may be embedded in the frame 4100.

The lens portion 4200 may include an optical member that transmits light or reflects light. For example, the lens portion 4200 may include glass, a transparent synthetic resin, or the like within the spirit and the scope of the disclosure.

In order for the user's eyes to recognize visual information, the lens portion 4200 may reflect an image by an optical signal transmitted from the projector of the frame 4100 by a rear surface of the lens portion 4200 (for example, a surface facing the user's eye). For example, the user may recognize visual information such as time and date displayed on the lens part 4200. In this case, the projector and/or the lens portion 4200 may be a type of display device. The display device 1200 may be applied to the projector and/or the lens portion 4200.

Referring to FIG. 19, the display system 1000 of FIG. 15 may be applied to a head-mounted display device 500.

The head-mounted display device 5000 may be a wearable electronic device that may be worn on the user's head. For example, the head-mounted display device 5000 may be a wearable device for virtual reality or mixed reality.

The head-mounted display device 5000 may include a head-mounted band 5100 and a display device accommodation case 5200. The head-mounted band 5100 may be connected to the display device accommodation case 5200. The head-mounted band 5100 may include a horizontal band and/or a vertical band for fixing the head-mounted display device 5000 to the user's head. The horizontal band may be configured to surround the side portion of the user's head, and the vertical band may be configured to surround the upper portion of the user's head. However, embodiments are not limited thereto. For example, the head-mounted band 5100 may be implemented in the form of a spectacle frame, a helmet, or the like within the spirit and the scope of the disclosure.

The display device accommodation case 5200 may accommodate the display system 1000 and/or the display device 1200.

While this disclosure has been described in connection with what is considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A lighting test method of a plurality of light emitting elements that include a second semiconductor layer, an active layer, a first semiconductor layer, and an electrode portion sequentially stacked on a growth substrate and spaced apart from each other, comprising:
forming an electric field between a probe card electrically contacting the electrode portion on the plurality of light emitting elements, and a conductive plate facing the second semiconductor layer below the growth substrate; and
testing whether the plurality of light emitting elements are lighted.

2. The lighting test method of claim 1, wherein the probe card includes:
a probe substrate disposed on the plurality of light emitting elements; and
a plurality of probe pins protruding in a direction from the probe substrate toward the plurality of light emitting elements.

3. The lighting test method of claim 2, wherein the electrode portion of each of the plurality of light emitting elements electrically contacts a corresponding probe pin among the plurality of probe pins.

4. The lighting test method of claim 1, wherein the growth substrate is disposed between the conductive plate and the second semiconductor layer in the forming of the electric field.

5. The lighting test method of claim 4, wherein the conductive plate directly contacts a lower surface of the growth substrate in the forming of the electric field.

6. The lighting test method of claim 1, wherein the testing of whether the plurality of light emitting elements are lighted includes:
obtaining an image by imaging the plurality of light emitting elements with an optical test unit; and
checking whether light is emitted in areas corresponding to the plurality of light emitting elements, in the image.

7. The lighting test method of claim 6, wherein the optical test unit images the plurality of light emitting elements on the probe card.

8. The lighting test method of claim 6, wherein
the optical test unit images the plurality of light emitting elements below the conductive plate, and
the conductive plate includes a light-transmissive material.

9. The lighting test method of claim 1, further comprising:
removing a defective light emitting element among the plurality of light emitting elements from the growth substrate after the testing of whether the plurality of light emitting elements are lighted.

10. A lighting test system comprising:
a growth substrate;
a plurality of light emitting elements that include a second semiconductor layer, an active layer, a first semiconductor layer, and an electrode portion sequentially stacked each other on the growth substrate, the plurality of light emitting elements being spaced apart from each other;
a probe card disposed on the plurality of light emitting elements and moving in a direction toward the plurality of light emitting elements to electrically contact the electrode portion;
a conductive plate disposed below the growth substrate and moving in a direction toward the growth substrate; and
an optical test unit disposed on the probe card.

11. The lighting test system of claim 10, wherein the probe card includes:
a probe substrate disposed on the plurality of light emitting elements; and
a plurality of probe pins protruding in a direction from the probe substrate toward the plurality of light emitting elements.

12. The lighting test system of claim 10, further comprising:
a power source electrically connected to each of the probe card and the conductive plate.

13. The lighting test system of claim 10, wherein the second semiconductor layer directly contacts an upper surface of the growth substrate.

14. The lighting test system of claim 10, wherein the second semiconductor layer includes:
a first doped portion disposed below the active layer and having a first average doping concentration;
a second doped portion disposed below the first doped portion and having a second average doping concentration lower than the first average doping concentration; and
a third doped portion disposed below the second doped portion and having a third average doping concentration lower than the second average doping concentration.

15. The lighting test system of claim 10, wherein the electrode portion further includes:
an auxiliary electrode electrically contacting the first semiconductor layer on the first semiconductor layer; and
a bonding electrode electrically connected to the auxiliary electrode on the auxiliary electrode.

16. The lighting test system of claim 15, wherein the auxiliary electrode includes a light-transmissive material.

17. The lighting test system of claim 15, wherein a planar area of the bonding electrode is smaller than a planar area of the first semiconductor layer.

18. The lighting test system of claim 15, wherein the electrode portion further includes:
a reflective electrode disposed between the auxiliary electrode and the bonding electrode.

19. The lighting test system of claim 18, wherein a planar area of the reflective electrode is smaller than a planar area of the first semiconductor layer.

20. A lighting test system comprising:
a growth substrate;
a plurality of light emitting elements that include a second semiconductor layer, an active layer, a first semiconductor layer, and an electrode portion sequentially stacked each other on the growth substrate, the plurality of light emitting elements being spaced apart from each other;
a probe card disposed on the plurality of light emitting elements and moving in a direction toward the plurality of light emitting elements to electrically contact the electrode portion;
a conductive plate disposed below the growth substrate and moving in a direction toward the above growth substrate; and
an optical test unit disposed on the conductive plate,
wherein the conductive plate includes a light-transmissive material.

21. An electronic device comprising:
a processor to provide input image data; and
a display device to display an image based on the input image data,
wherein the display device includes a plurality of light emitting elements,
wherein the plurality of light emitting elements is manufactured by performing the lighting test method according to claim 1.
